(19) United States
(12) Patent Application Publication
(10) Pub. No.: US 2026/0149238 A1
(43) Pub. Date: May 28, 2026

(54) NON-C-PLANE GROUP III-NITRIDE-BASED VCSELS WITH NANOPOROUS DISTRIBUTED BRAGG REFLECTOR MIRRORS

(71) Applicant: UNM RAINFOREST INNOVATIONS, Albuquerque, NM (US)

(72) Inventors: Daniel F. Feezell, Albuquerque, NM (US); Morteza Monavarian, Albuquerque, NM (US); Saadat M. Mishkat-Ul-Masabih, Albuquerque, NM (US)

(21) Appl. No.: 19/178,246

(22) Filed: Apr. 14, 2025

Related U.S. Application Data
(62) Division of application No. 17/185,868, filed on Feb. 25, 2021, now Pat. No. 12,308,615.
(60) Provisional application No. 62/981,300, filed on Feb. 25, 2020.

(51) Int. Cl. H01S 5/183; H01S 5/02; H01S 5/024; H01S 5/042; H01S 5/227; H01S 5/32; H01S 5/343

(52) U.S. Cl. CPC H01S 5/18363; H01S 5/0206; H01S 5/02469; H01S 5/042; H01S 5/18308; H01S 5/18347; H01S 5/18355; H01S 5/18361; H01S 5/18369; H01S 5/2275; H01S 5/32025; H01S 5/34333

(57) ABSTRACT

An electrically injected vertical-cavity surface emitting laser (VCSEL) and a method of manufacturing the same is disclosed. The electrically injected VCSEL includes a non-c-plane substrate and a nanoporous bottom distributed Bragg reflector (DBR) comprising a plurality of alternating highly doped III-nitride layers and unintentionally doped III-nitride layers formed above the substrate.

### CROSS REFERENCE TO RELATED APPLICATIONS

This application is a divisional application of U.S. application Ser. No. 17/185,868, filed on Feb. 25, 2021, now allowed, of which claims priority to U.S. Provisional Patent Application No. 62/981,300 , filed on Feb. 25, 2020, the disclosures of which are hereby incorporated by reference in their entireties.

### GOVERNMENT RIGHTS

This disclosure was made with Government support under Grant No. 1454691 awarded by the National Science Foundation. The Government has certain rights in the invention.

### FIELD

This disclosure relates generally to non-c-plane Group III-nitride-based VCSELs with nanoporous distributed Bragg reflector mirrors.

### BACKGROUND

GaN-based vertical-cavity surface-emitting lasers (VCSELs) have drawn interest in recent years for their potential applications in data storage, laser printing, solid-state lighting, optical communications, sensing, and displays. Several research groups have demonstrated electrically injected GaN-based VCSELs utilizing different growth and fabrication techniques to address the many challenges associated with III-nitride materials. One such challenge is fabrication of high-quality conductive epitaxial distributed Bragg reflectors (DBRs).

With the commercialization of light emitting diodes (LEDs) and edge-emitting lasers diodes (LDs) in the violet-blue spectral region, group III-nitride based optoelectronic devices have undergone significant advancements in terms of device performance and reliability. As such, many lighting, communication, data storage, display, and sensing applications now utilize GaN-based light emitters. Among these light emitters, vertical-cavity surface-emitting lasers (VCSELs) have garnered much attention in recent years due to their inherent advantages over edge-emitting lasers. The significantly shorter cavity lengths in VCSELs often allow for single-longitudinal-mode operation, while a small aperture diameter also enables single-transverse-mode operation in some cases. Furthermore, the small device size allows the fabrication of high-density 2D arrays, thereby dramatically reducing the development cost per device. Unlike edge-emitters, the emission of VCSELs is normal to the device surface and has a circular beam profile with low divergence angle, thus VCSELs are highly efficient for fiber coupling and on-wafer testing. Similarly, the small cavity volume results in fundamentally low threshold current and high modulation bandwidth at low bias currents. III-nitride VCSELs are typically fabricated on the polar c-plane orientation that suffers from polarization-related electric fields in the active region and low per-pass gain. However, the nonpolar m-plane orientation eliminates internal electric fields, causing the uniform overlap of the electron and hole wave functions. Additionally, the in-plane gain anisotropy in the nonpolar orientation enables polarization-pinned emission along the a-direction, which is often desired in applications such as polarization-pinned arrays or atomic clocks.

Optically and electrically pumped GaN-based VCSELs have been demonstrated by many research groups in the past decade. One challenge for GaN-based VCSELs is the absence of high quality, high reflectance epitaxial DBRs. Since a DBR consists of layers of alternating material, it is necessary that the two materials are lattice-matched to prevent the formation of dislocations. Only Al_{0.82}In _{0.18}N can be lattice-matched to GaN, but the refractive index difference between the layers is only ˜0.2, requiring more than 40-pairs to obtain a peak reflectance >99.9%. Thus, very long growth times in metal organic chemical vapor deposition (MOCVD) are necessary (˜8 hours for 40-pairs) and maintaining the proper ternary alloy composition in the group-III elements is very difficult. Dielectric DBRs are often used in III-nitride VCSELs as a substitute for epitaxial DBRs due to the wide variety of materials available permitting high index contrast and ease of deposition processes. However, the use of dielectric DBRs involves complex fabrication techniques to access the backside of the cavity and device yield per wafer may be low. The non-conductive nature of dielectric materials also causes poor thermal and electrical performance of the VCSELs.

### SUMMARY

According to examples of the present disclosure, an electrically injected III-nitride vertical-cavity surface emitting laser (VCSEL) is disclosed. The electrically injected III-nitride VCSEL comprises a non-c-plane substrate and a nanoporous bottom distributed Bragg reflector (DBR) comprising a plurality of alternating highly doped III-nitride layers and unintentionally doped III-nitride layers formed above the substrate.

Various additional features can be included in the electrically injected III-nitride VCSEL including one or more of the following features. An index of refraction of the highly doped III-nitride layers is controlled by an amount of porosity in the highly doped III-nitride layers, wherein the porosity comprises a plurality of subwavelength air voids. A pore size of the plurality of subwavelength air voids is determined based on an electrochemical etch bias voltage, a doping level, and an etchant solution. A density of the plurality of subwavelength air voids (porosity) is between about 20% and about 80%, or about 30% and about 70%, or about 40% and about 60%, or about 50%. The density of the plurality of subwavelength air voids is controlled based on a concentration of Si-doping. A higher density of the plurality of subwavelength air voids is inversely proportional to a number of layers of the plurality of alternating highly doped III-nitride layers and unintentionally doped III-nitride layers to obtain high mirror reflectance. The highly doped III-nitride layers and the unintentionally doped III-nitride layers can comprise GaN, InₓGa₁₋ₓN, or AlₓGa₁₋ₓN. The non-c-plane III-nitride substrate is an m-plane III-nitride substrate. The non-c-plane III-nitride substrate is at an angle between a c-plane and an m-plane of the III-nitride substrate. A majority of radiation emitted by the VCSEL has its electric field polarization pinned along an a-direction or perpendicular to the projection of the c-axis of the non-c-plane III-nitride substrate. An electric field of emitted radiation is polarized along an a-direction or perpendicular to the projection of the c-axis. The radiation comprises UV, visible, or infrared. The electrically injected III-nitride VCSEL further comprises a dielectric DBR formed over the nanoporous bottom distributed DBR. The substrate comprises a III-nitride material. The electrically injected III-nitride VCSEL further comprises an unintentionally doped (UID) GaN heat spreading layer; an n+GaN contact layer; an n−GaN cladding layer; an active region; an electron blocking layer; a p−GaN cladding layer; an p+GaN contact layer; an indium tin oxide (ITO) layer; a cavity spacer; and a top DBR. The electrically injected III-nitride VCSEL further comprises one or more ion-implanted apertures. In some examples, a tunnel junction can be used in place of the ITO layer.

According to examples of the present disclosure, a method for fabricating an electrically injected III-nitride vertical-cavity surface emitting laser (VCSEL) is disclosed. The method comprises providing an epitaxial structure comprising, a non-c-plane substrate, a bottom nanoporous distributed Bragg reflector (DBR) comprising a plurality of alternating highly doped III-nitride layers and unintentionally doped III-nitride layers on the substrate, a UID III-nitride heat spreading layer, an n+ III-nitride contact layer, an n-III-nitride cladding layer, an active region, an electron blocking layer, a p-III-nitride cladding layer, and a p+ III-nitride contact layer; etching a mesa to expose the n+ III-nitride contact layer; patterning to define one or more current apertures; ion implanting one or more apertures; depositing a layer of SiO₂ to protect the active region and contact layers; etching deep trenches to expose sidewalls of the bottom DBR structure; and etching to selectively porosify the highly doped III-nitride layers to form a nanoporous DBR.

Various additional features can be included in the method of fabricating the electrically injected III-nitride VCSEL including one or more of the following features. The method further comprises removing the layer of SiO₂; patterning a layer of SiNₓ on the mesa and the trench to passivate sidewalls of the active region and the nanoporous DBR; depositing an ITO layer; deposing an n metal and a p metal; depositing a cavity spacer; and deposing a top dielectric DBR. The substrate is a non-c-plane orientation. The substrate is at an angle between a c-plane and an m-plane of the substrate, including the m-plane or angles beyond the m-plane to minus c-plane (N face).

According to examples of the present disclosure, an electrically injected nonpolar vertical-cavity surface emitting laser (VCSEL) is disclosed. The electrically injected nonpolar VCSEL comprises an m-plane III-nitride substrate; and a lattice-matched nanoporous bottom distributed Bragg reflector (DBR) comprising a plurality of alternating highly doped III-nitride layers and unintentionally doped III-nitride layers on the substrate, wherein an index of refraction of the highly doped III-nitride layers is controlled by a plurality of subwavelength air voids.

Various additional features can be included in the electrically injected nonpolar VCSEL including one or more of the following features. The highly doped III-nitride layers and unintentionally doped III-nitride layers comprise GaN. The electrically injected nonpolar VCSEL can further comprise a UID GaN layer; an n+GaN contact layer; an n−GaN cladding layer; an active region; an electron blocking layer; a p−GaN cladding layer; an p+GaN contact layer; an ITO layer; a cavity spacer; and a top DBR. The electrically injected nonpolar VCSEL can further comprise one or more ion-implanted apertures.

According to examples of the present disclosure, a method for fabricating an electrically injected nonpolar vertical-cavity surface emitting laser (VCSEL) is disclosed. The method comprises providing an epitaxial structure comprising, an m-plane GaN substrate, a bottom distributed Bragg reflector (DBR) comprising a plurality of alternating highly doped GaN layers and unintentionally doped GaN layers on the substrate, a UID GaN heat spreading layer, an n+GaN contact layer, an n−GaN cladding layer, an active region, an electron blocking layer, a p−GaN cladding layer, and an p+GaN contact layer; etching a mesa to expose the n+GaN contact layer; patterning to define one or more current apertures; ion implanting one or more apertures; depositing a layer of SiO₂ to protect the active region and contact layers; etching deep trenches to expose sidewalls of the lattice-matched bottom DBR; and etching to selectively porosify the highly doped GaN layers to form a nanoporous DBR.

Various additional features can be included in the method for fabricating the electrically injected nonpolar VCSEL including one or more of the following features. The method can further comprise removing the layer of SiO₂; patterning a layer of SiNₓ on the mesa and the trench to passivate sidewalls of the active region and the nanoporous DBR; depositing an ITO layer; deposing an n metal and a p metal; depositing a cavity spacer; and deposing a top dielectric DBR.

### BRIEF DESCRIPTION OF THE FIGURES

Various features of the embodiments can be more fully appreciated, as the same become better understood with reference to the following detailed description of the embodiments when considered in connection with the accompanying figures, in which:

FIG. 1A, FIG. 1B, FIG. 1C, and FIG. 1D are prior art and show polar and nonpolar crystal characteristics, where FIG. 1A shows a polar example, FIG. 1B shows a nonpolar example, FIG. 1C show a plot of intensity vs. wavelength for different polarizations, and FIG. 1D shows a polar plot of the emission intensity from an m-plane VCSEL.

FIG. 2A shows a plot of modal gain vs. current density plot for 1 QW to 8 QWs with a QW thickness of 4 nm and barrier thickness of 2 nm. TMM simulated threshold modal gain is overlaid on the plot to determine which yields the lowest threshold current density. FIG. 2B shows results of a TMM simulation of the cavity mode intensity and refractive index profile for a 6-QW design.

FIG. 3A shows a plot of spontaneous emission EL spectrum of the nanoporous VCSEL sample. [Inset] Epilayer stack of the sample showing the layer thicknesses and the repetitions. FIG. 3B shows plots of a quick-test spontaneous emission L-I-V characteristics of the sample with a turn-on at 4.5 V and a 3.75 mW output power at 100 mA.

FIGS. 4A-4L show processing steps for the fabrication of the m-plane nanoporous VCSEL.

FIG. 5 shows mages of an angled topographic view of the VCSEL structure and cross-sectional SEM image of a representative bottom nanoporous DBR.

FIG. 6 shows additional images of an angled topographic view of the VCSEL structure and cross-sectional SEM image of a representative bottom nanoporous DBR.

FIG. 7A shows a L-J-V plot of a 20 μm diameter nanoporous VCSEL under pulsed operation. FIG. 7B shows an emission spectrum under various pump currents and the corresponding near-field images of the aperture region.

FIG. 8A shows a polar plot showing stable polarization pinned emission along [12̅10] (a-direction). FIG. 8B shows a spectrum when the polarizer angle is perpendicular and parallel to [0001].

FIG. 9A shows an axisymmetric COMSOL simulation of the nanoporous VCSEL showing the temperature profile and (inset) heat flow in the cavity layers. It also shows a microscope image of a device with p-metal damage due to heating at 3% duty cycle. FIG. 9B shows a plot of Zₜ vs. cavity length for the nanoporous VCSEL with different aperture sizes. Overlaid are the thermal resistances of reported CW-RT VCSELs by NCTU, Meijo-Stanley, and UCSB.

FIG. 10 shows two examples of the near-field emission pattern and mode simulation of a 20 μm diameter nanoporous VCSEL aperture.

FIG. 11A, FIG. 11B, FIG. 11C, and FIG. 11D show plots showing the (FIG. 11A) output power/intensity, (FIG. 11B) slope efficiency, (FIG. 11C) threshold current/current density, and (FIG. 11D) differential resistance as a function of the aperture size. The data represent the average of 50 device measurements with error bars.

### DETAILED DESCRIPTION

Reference will now be made in detail to example implementations, illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

Generally speaking, an electrically injected vertical-cavity surface emitting laser (VCSEL) and a method of manufacturing the same is disclosed. The electrically injected VCSEL includes a non-c-plane substrate and an epitaxial nanoporous bottom distributed Bragg reflector (DBR) comprising a plurality of alternating highly doped III-nitride layers and unintentionally doped III-nitride layers formed above the substrate. The non-c-plane III-nitride substrate is at an angle between a c-plane and an m-plane of the III-nitride substrate, including the m-plane or anything beyond the m-plane to minus c-plane (N face). The highly doped III-nitride layers and the unintentionally doped III-nitride layers can comprise GaN, InₓGa₁₋ₓN, or AlₓGa₁₋ₓN. Other group III materials can also be used.

The index of refraction of the highly doped III-nitride layers is controlled by an amount of porosity in the highly doped III-nitride layers, wherein the porosity comprises a plurality of subwavelength air voids. A pore size of the subwavelength air voids is determined based on an electrochemical etch bias voltage, a doping level, and an etchant solution. A density of the plurality of subwavelength air voids is between about 20% and about 80%, or about 30% and about 70%, or about 40% and about 60%, or about 50%. The density of the plurality of subwavelength air voids is controlled based on a concentration of Si-doping. The porosity of the subwavelength air voids (complete etching at 100% porosity also viable) is inversely proportional to a number of pairs of alternating highly doped III-nitride and unintentionally doped III-nitride layers needed to obtain high mirror reflectance.

In some examples, a majority, such as greater than 50%, greater than 75%, greater than 90%, of radiation emitted by the VCSEL is polarization-pinned along an a-direction of the non-c-plane III-nitride substrate. An electric field of the emitted radiation is polarized along an a-direction. The radiation comprises UV, visible, or infrared. The electrically injected III-nitride VCSEL further comprises a dielectric DBR formed over the epi-layers and the nanoporous bottom DBR. The substrate comprises a III-nitride material. The electrically injected III-nitride VCSEL further comprises an unintentionally doped (UID) GaN heat spreading layer; an n+GaN contact layer; an n−GaN cladding layer; an active region; an electron blocking layer; a p−GaN cladding layer; an p+GaN contact layer; an indium tin oxide (ITO) layer; a cavity spacer; and a top dielectric DBR. The electrically injected III-nitride VCSEL further comprises one or more ion-implanted apertures.

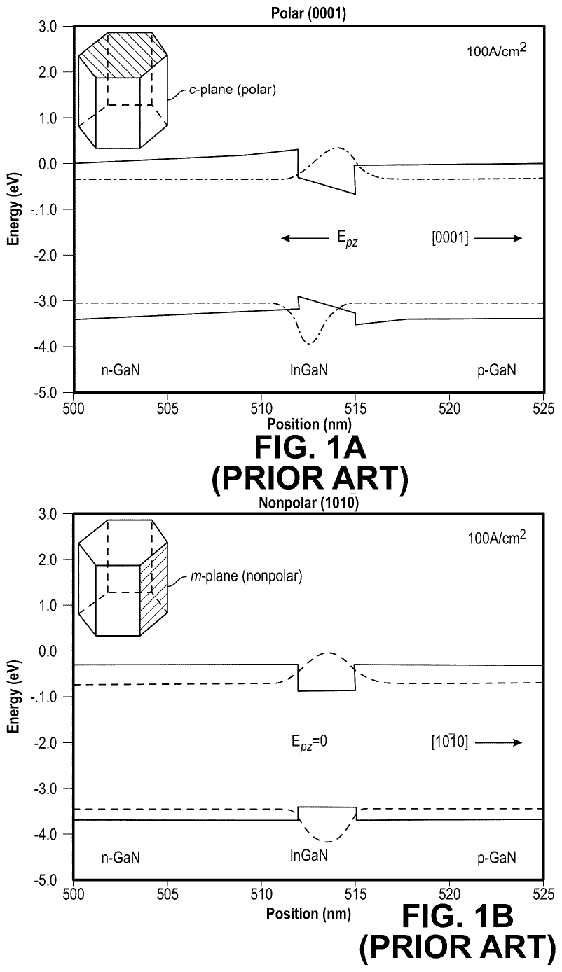

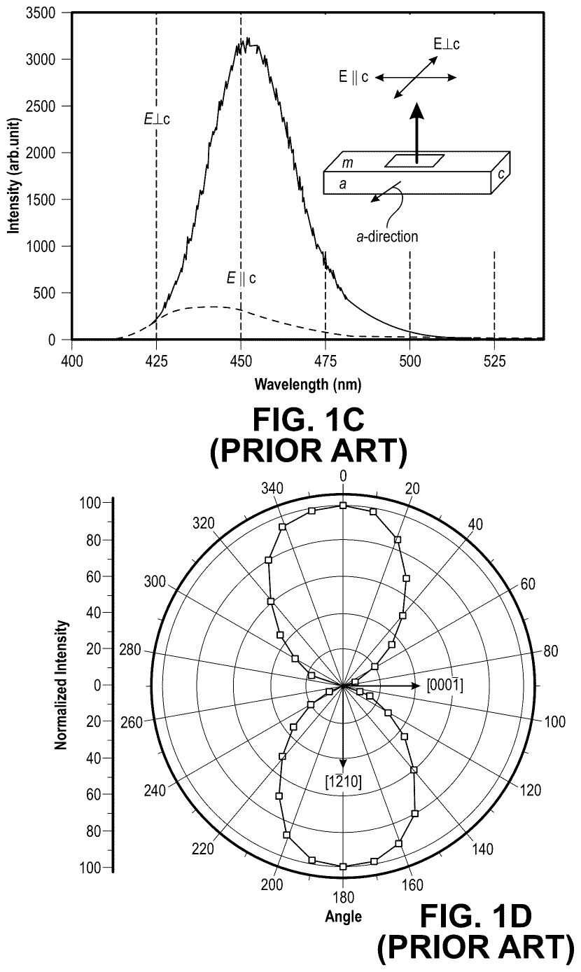

Incorporating subwavelength air-voids or nanopores in alternating layers allows high-refractive-index-contrast between the layers. The nanoporous layers are created by the anodic electrochemical (EC) etching of highly doped n-type GaN in certain acids. The selectivity of the nanopores in the n-type doped layers effectively lowers the refractive index compared to the adjacent unintentionally doped bulk GaN layers. Using this technique a DBR mirror reflectance >98% was demonstrated with only 15 pairs. Later, an optically pumped 2-λ hybrid VCSEL that exhibited a single longitudinal lasing mode at 462 nm with a threshold power density of ˜5 kW/cm² and a FWHM of ˜0.12 nm was developed. Finally,, the first electrically injected nonpolar m-plane GaN-based VCSELs using lattice-matched nanoporous bottom DBRs. Lasing under pulsed operation at room temperature was observed near 409 nm with a linewidth of ˜0.6 nm and a maximum output power of ˜1.5 mW. All tested devices were linearly polarized and polarization-pinned in the a-direction with a polarization ratio of 0.94. FIG. 1A, FIG. 1B, FIG. 1C, and FIG. 1D are prior art and show polar and nonpolar crystal characteristics, where FIG. 1A shows a polar example (0001) along the c-plane, FIG. 1B shows a nonpolar example (101̅0) along the m-plane, FIG. 1C show a plot of intensity vs. wavelength, and FIG. 1D shows a polar plot. In FIG. 1C, a crystal is shown with a, c, and m planes labeled. The a-direction is perpendicular to the a-plane, the m-direction is perpendicular to the m-plane, and the c-direction is perpendicular to the c-plane.

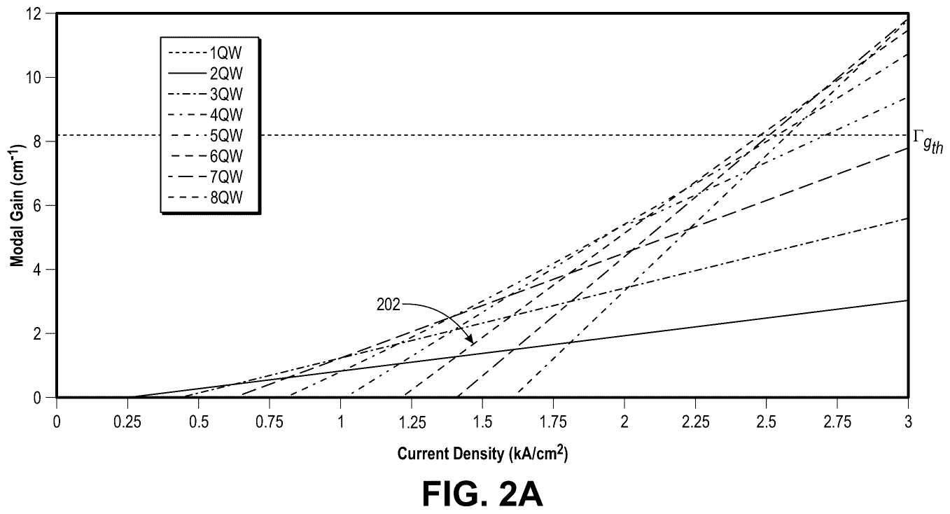

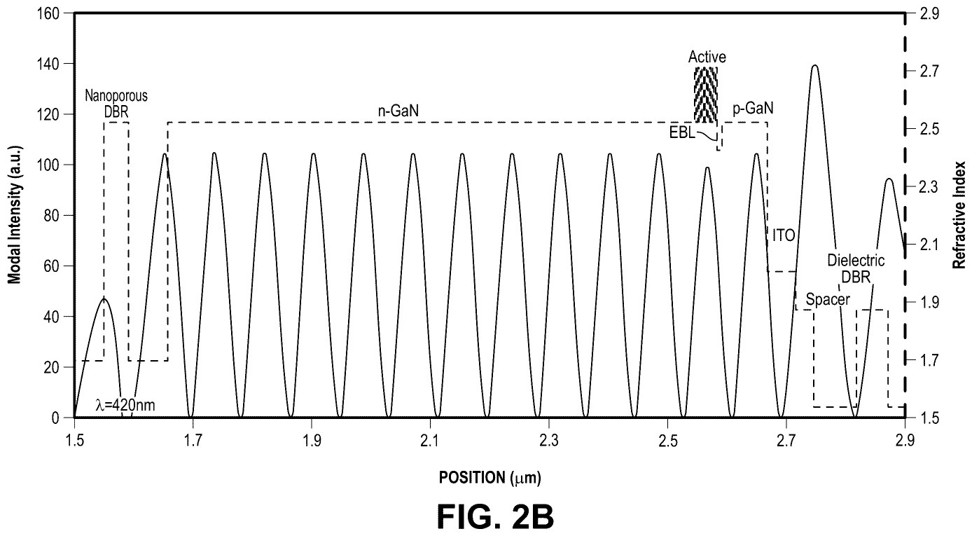

FIG. 2A shows a plot of modal gain vs. current density plot for 1 QW to 8 QWs with a QW thickness of 4 nm and barrier thickness of 2 nm. TMM simulated threshold modal gain is overlaid on the plot to determine which yields the lowest threshold current density. FIG. 2B shows results of a TMM simulation of the cavity mode intensity and refractive index profile for a 6-QW design.

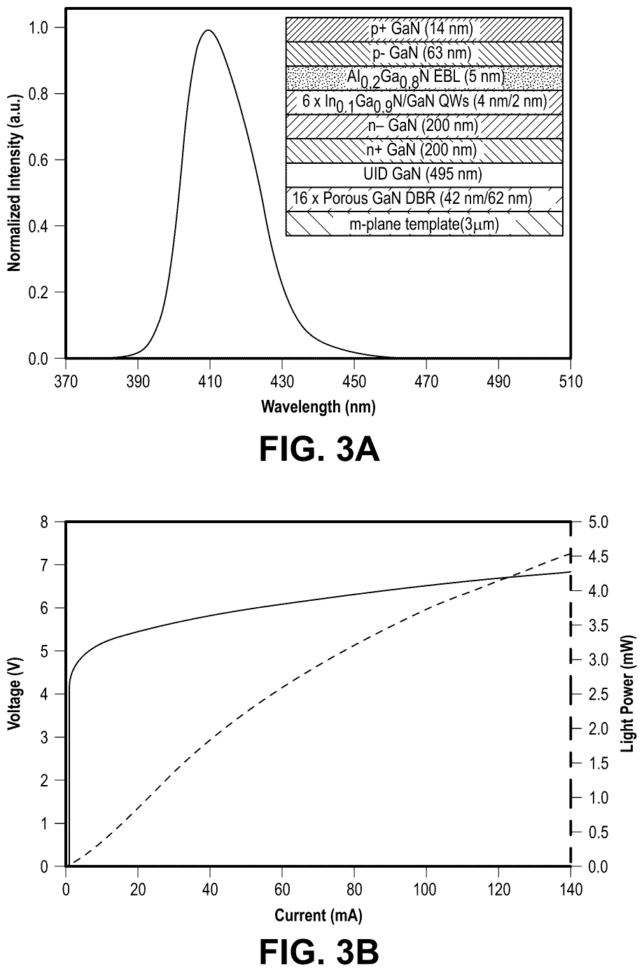

As shown in FIG. 2A, plots of the gain curves for 1-8 QWs with 2 nm barriers. The standing-wave and the refractive index profile of the cavity with an effective optical thickness of 8-□ (L_{eff}×n_{eff}≈1453 nm×2.26) is illustrated in FIG. 2B, with the QWs positioned at a longitudinal mode peak and the indium tin oxide (ITO) at a null to maximize gain and minimize loss. The threshold modal gain of the cavity obtained from the TMM simulation was ˜8.4 cm⁻¹. Overlaying this value on top of FIG. 2A, it can be seen that the lowest current density for this modal gain can be achieved with 6 QWs, highlighted by line 202. The electron blocking layer (EBL) comprises a 5 nm p-doped Al_{0.2}Ga_{0.8}N layer. FIG. 3A shows a plot of spontaneous emission EL spectrum of the nanoporous VCSEL sample. [Inset] Epilayer stack of the sample showing the layer thicknesses and some layer repetitions. FIG. 3B shows plots of the spontaneous emission quick-test L-I-V characteristics of the sample with a turn-on at 4.5 V and a 3.75 mW output power at 100 mA.

An m-plane VCSEL sample was then grown with the epilayers consisting of a 3-μm-thick n-GaN template, 16 pairs of alternating unintentionally doped (UID)/n+GaN (Si-doping concentration ˜1×10¹⁹ cm⁻³) layers with thicknesses of 42 nm/ 62 nm for the bottom DBR, 495 nm of unintentionally doped (UID) GaN for thermal spreading, a 200 nm n+GaN contact layer, a 200 nm n-GaN cladding layer, a six-pair In_{0.1}Ga_{0.9}N/GaN active region with thicknesses of 4 nm/ 2 nm emitting at ˜407 nm, a 5 nm p-Al_{0.2}Ga_{0.8}N electron blocking layer, a 63 nm p−GaN cladding layer, and a 14 nm p+GaN contact layer. The spontaneous emission EL spectrum and spontaneous emission L-I-V characteristics of the sample were collected after growth and before fabrication and are plotted in FIG. 3A and FIG. 3B, respectively. The actual peak emission wavelength was 410 nm. The device turn-on was around 4.5 V with a series resistance of ˜10 Ω. Both the turn-on voltage and series resistance can be improved with the optimization of the EBL and p−GaN layers.

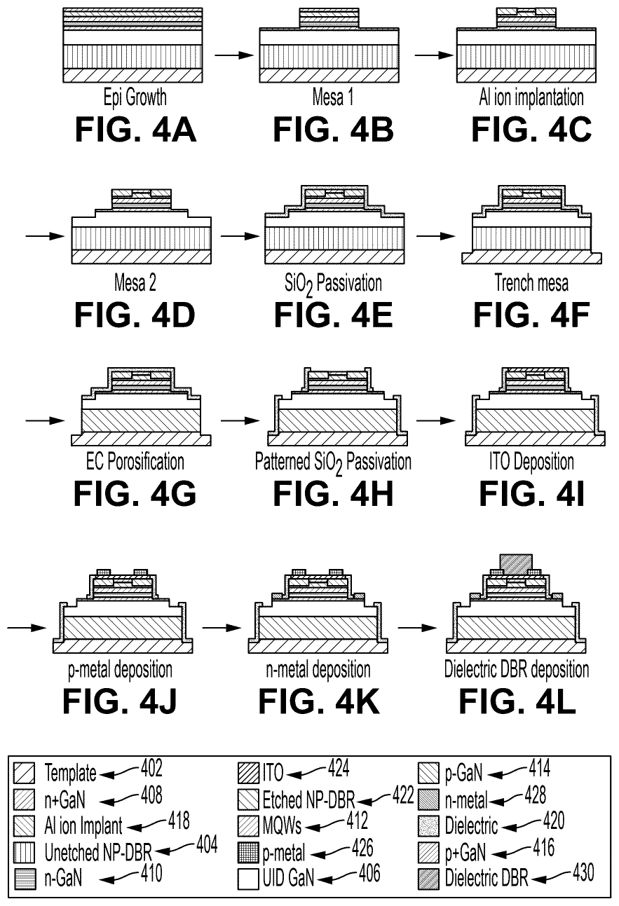

FIGS. 4A-4L show processing steps for the fabrication of the m-plane nanoporous VCSEL. FIG. 4A shows an epitaxy growth step comprising template layer 402, unetched NP-DBR layer 404, UID GaN thermal layer 406, n+ GaN layer 408, n− GaN layer 410, MQW active layers 412, p− GaN layer 414, and p+ GaN layer 416. FIG. 4B shows a formation of Mesa 1 from the arrangement of FIG. 4A. FIG. 4C shows Al ion implantation on the arrangement of FIG. 4B by Al ion implanting specific areas 418. FIG. 4D shows formation of Mesa 2 from the arrangement of FIG. 4C. FIG. 4E shows a SiO₂ passivation layer on a top surface and sidewalls of Mesa 2 from the arrangement of FIG. 4D by deposition of dielectric layer 420. FIG. 4F shows formation of a trench etch based on the arrangement of FIG. 4E. FIG. 4G shows an Electrochemical (EC) porosification based on the arrangement of FIG. 4F with porosified NP-DBR layer 422. FIG. 3H shows a patterned SiO₂ passivation layer based on the arrangement of FIG. 4G. FIG. 4I shows an ITO deposition layer 424 based on the arrangement of FIG. 4H where formation of the ITO deposition layer 424 is formed on a top surface of Al ion implant layer 418 and p+ GaN layer 416. FIG. 4J shows a p-metal deposition based on the arrangement of FIG. 4I by formation of p-metal layer 426 on a top surface of ITO deposition layer 424. FIG. 4K shows a n-metal deposition based on the arrangement of FIG. 4J by formation of n-metal layer 428 on a portion of a top surface of n+ GaN layer 408. FIG. 4L shows a dielectric DBR deposition based on the arrangement of FIG. 4K by formation of dielectric DBR layer 430 on a top surface of ITO deposition layer 424 and between n-metal layer 428.

Following the growth, the sample was fabricated according the to the process flow depicted in FIGS. 4A-4H. First, a mesa was etched (Mesa 1) using ICP etching to expose the n+GaN contact layer. Next, the sample was patterned with a Ti/Au hard mask to define the current apertures and then implanted with Al-ion. Aperture diameters of 5 μm, 10 μm, 15 μm, and 20 μm were defined in this step. After implantation, the Ti/Au hard mask was removed in aqua regia. A second mesa with a depth of 400 nm was ICP etched (Mesa 2) and followed by a blanket e-beam deposition of 150 nm SiO₂ to protect the active region and contact layers during the porosification step of the nanoporous DBRs. Next, deep trenches aligned along the c-direction were etched to expose the sidewalls of the DBR stack. Following this, the DBRs were EC etched for 14 hours to selectively porosify the highly doped n-type DBR layers using a bias voltage of 5 V at 100 rpm stirring. Complete porosification was confirmed when the two lateral etch fronts along the a-direction met at the center of the trench. Next, the blanket SiO2 was stripped in buffered HF and a patterned layer of SiNx was deposited across Mesa 1 and the trench to passivate the sidewalls of the active region and the nanoporous DBRs. Passivation of the DBR sidewalls was required to prevent the build-up of undeveloped PR from the subsequent steps. 50 nm of ITO was e-beam deposited and annealed under nitrogen ambient at 550° C. for 15 minutes, after which the p-metal and n-metal were deposited and consisted of Ti/Au (20 nm/300 nm) and Ti/Al/Ni/Au (20 nm/100 nm/50 nm/300 nm), respectively. Finally, a 30-nm-thick SiNₓ cavity spacer and the top dielectric DBR were blanket deposited using PECVD then patterned and etched down using RIE. The top DBR consists of 25 pairs of alternating λ/4n_{SiO2}-thick SiO₂ and λ/4n_{SiNx}-thick SiNₓ.

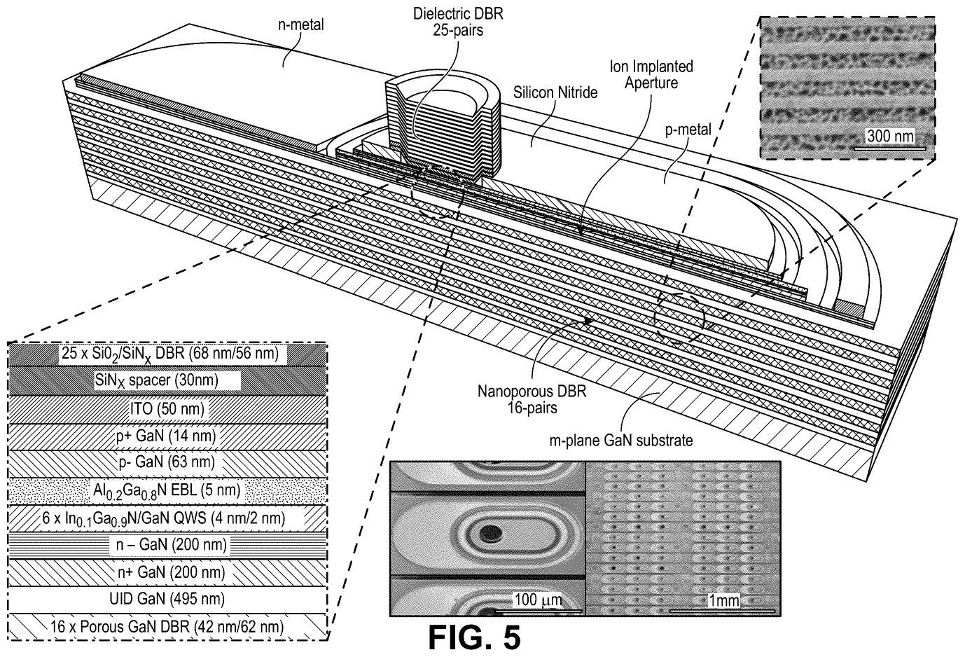

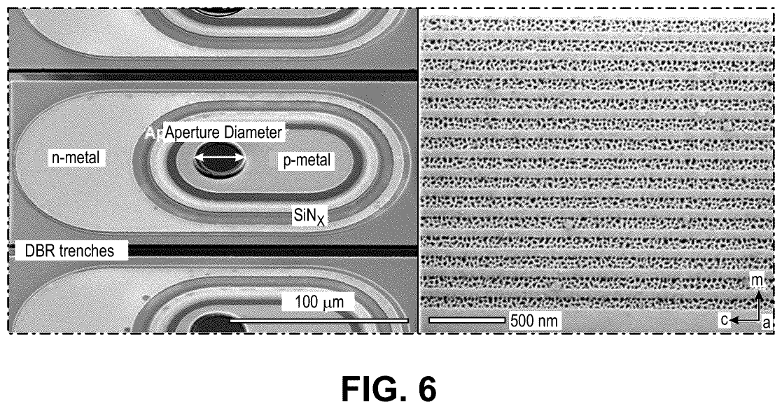

FIG. 5 shows a schematic illustration of the VCSEL structure, the epitaxial layer structure of the VCSEL, and SEM images of an angled topographic views of the VCSEL structure and cross-sectional SEM image of a representative bottom nanoporous DBR. FIG. 6 shows additional SEM images of an angled topographic view of the VCSEL structure and cross-sectional SEM image of a representative bottom nanoporous DBR.

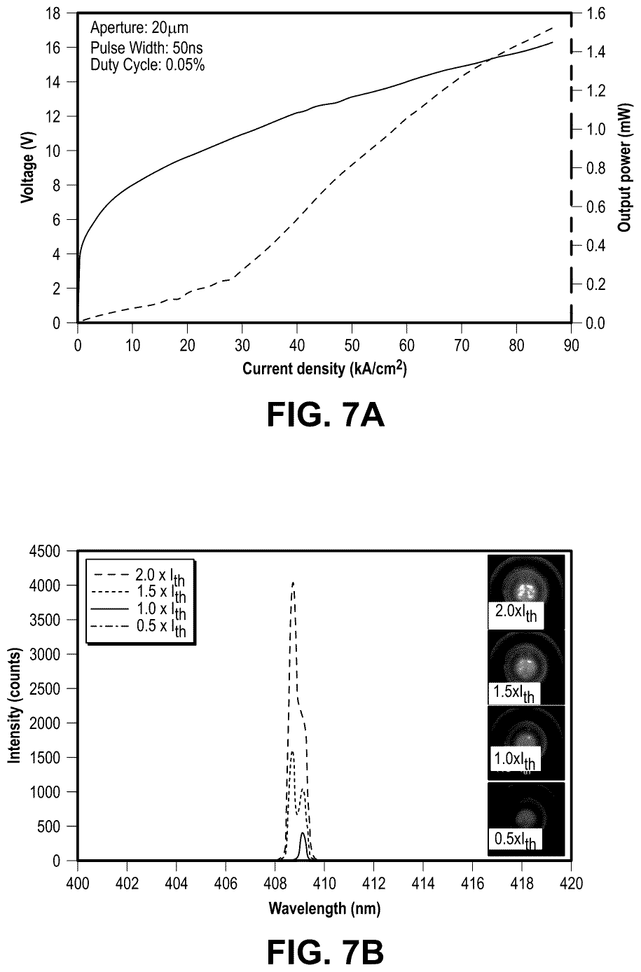

FIG. 7A shows an L-J-V plot of a 20-μm-diameter nanoporous VCSEL under pulsed operation. FIG. 7B shows an emission spectrum under various pump currents and the corresponding near-field images of the aperture region at various operating currents. As shown in FIG. 7A, the light-current density-voltage (L-J-V) characteristics of a VCSEL with a 20 μm diameter aperture is shown. The threshold current density is ˜20 kA/cm² and the maximum output power is 1.5 mW. As shown in FIG. 7B, the lasing spectrum for the same device, with a peak wavelength of 408.7 nm and a FWHM of 0.6 nm. The inset images show the intensity from the aperture area at various bias currents.

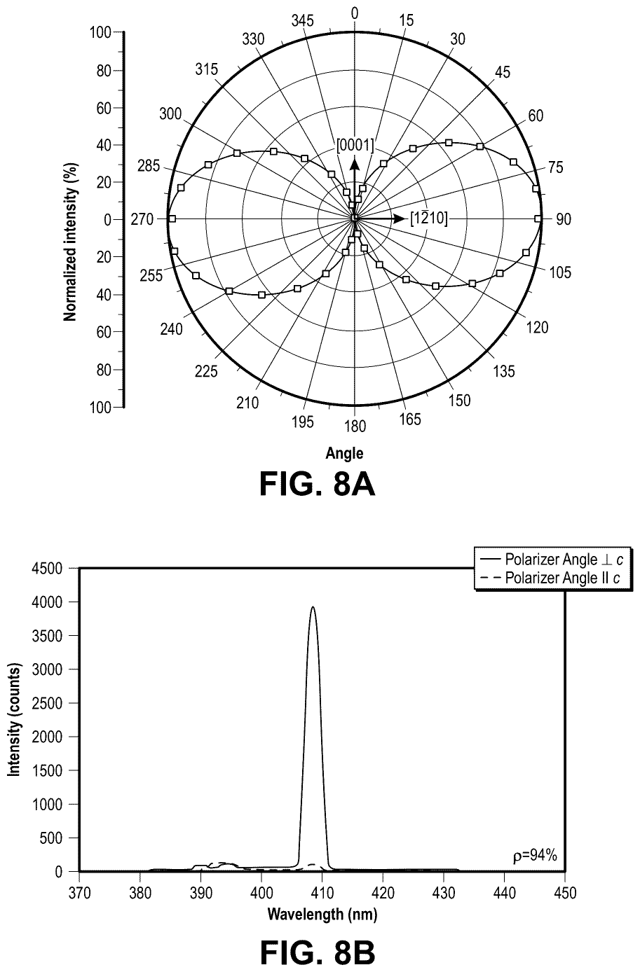

FIG. 8A shows a polar plot showing stable polarization pinned emission along [12̅10] (the a-direction). FIG. 8B shows a spectrum when the polarizer angle is perpendicular and parallel to [0001]. A plot of the normalized output power as a function of polarizer angle reveals that the emission is polarization pinned along the a-direction of the crystal. All tested devices showed polarization pinning along the a-direction. FIG. 8B shows the spectrum with the polarizer parallel and perpendicular to the c-direction. Maximum transmission is obtained with the polarizer perpendicular to the c-direction (along the a-direction). The measured polarization ratio was 0.94.

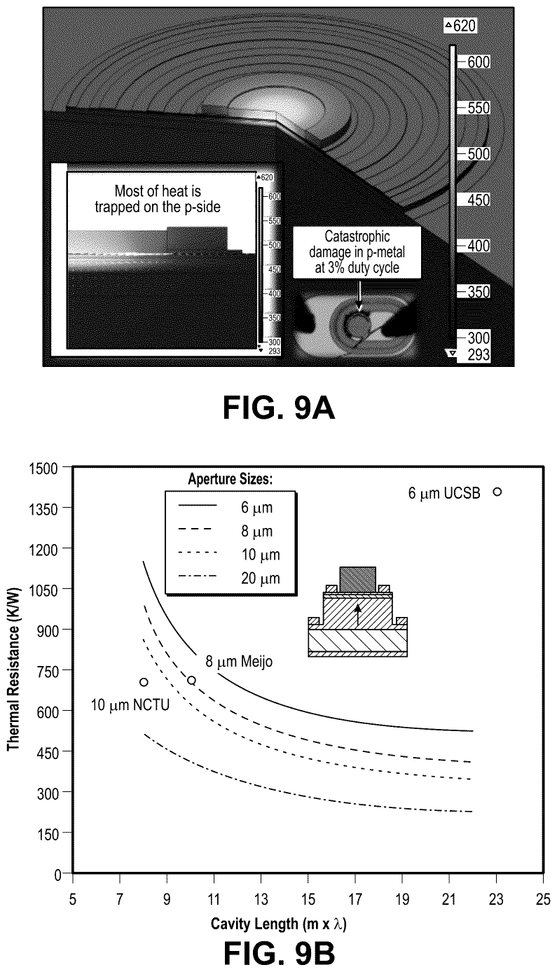

FIG. 9A shows an axisymmetric COMSOL™ simulation of the nanoporous VCSEL showing the temperature profile and (inset) heat flow in the cavity layers. It also shows a microscope image of a device with p-metal damage due to heating at 3% duty cycle. FIG. 9B shows a plot of thermal resistance (Zₜ) vs. cavity length for the nanoporous VCSEL with different aperture sizes. Overlaid are the thermal resistances of reported CW-RT VCSELs by other research groups.

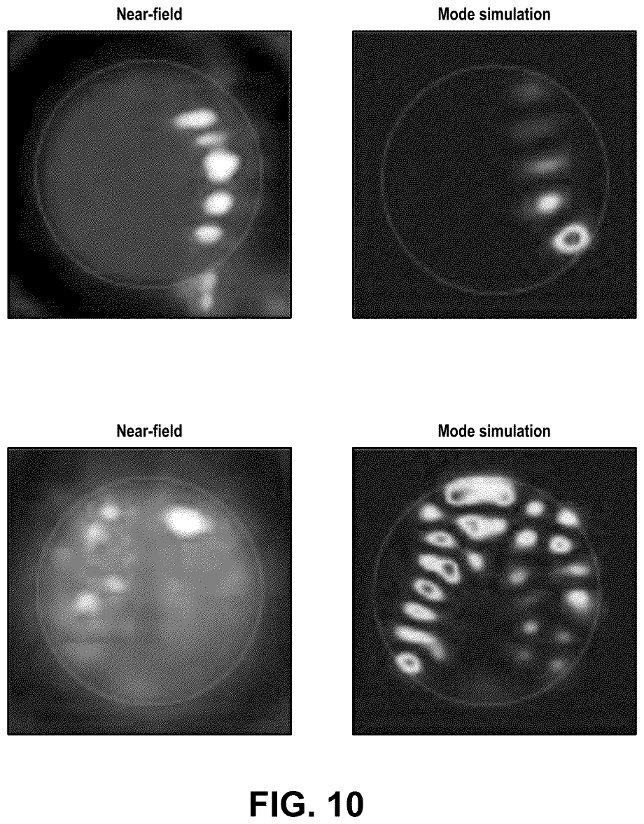

FIG. 10 shows two examples of the near-field emission pattern and mode simulation of a 20 μm diameter nanoporous VCSEL aperture. The random nature of the filamentation coupled with the distinct divide across the aperture by the nanoporous etch fronts strongly hinted that the filamentation may originate from the non-uniformity in the cavity resonance. This was verified by simulating a similar core-cladding model but with the addition of nanoscale regions with slightly higher refractive index scattered randomly throughout the core region. The small index change was calculated using Δn/n=Δ□/□, where Δ□ is the difference in wavelength obtained from the two peaks observed in our previous optical pumped VCSEL with □ being the dominant peak.

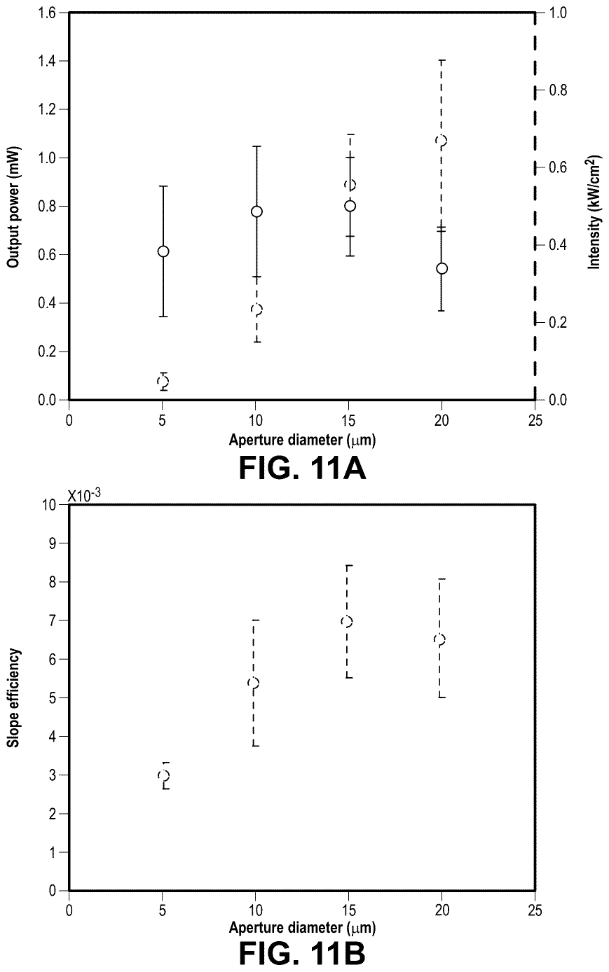

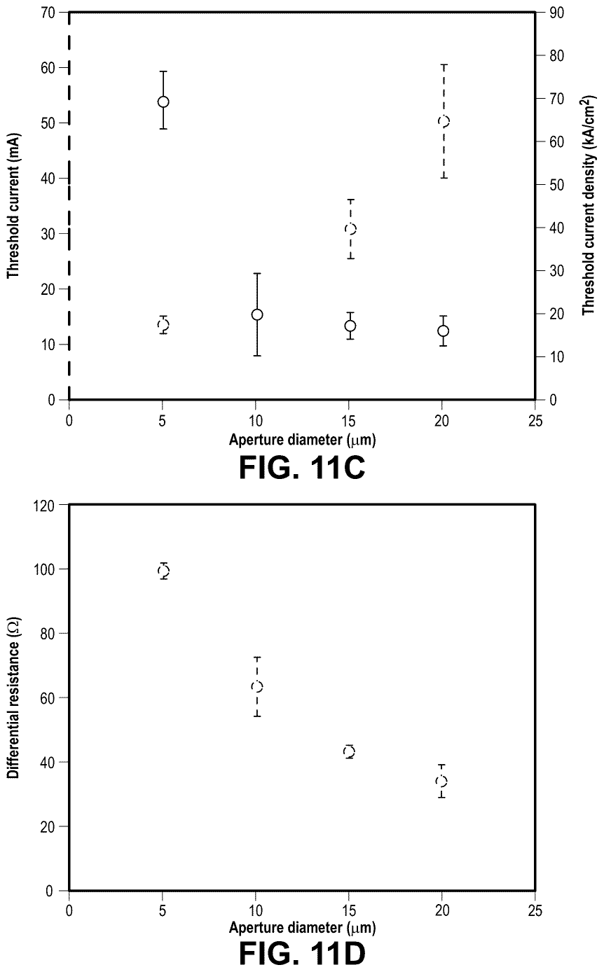

FIG. 11A, FIG. 11B, FIG. 11C, and FIG. 11D show plots showing the (FIG. 11A) output power/intensity, (FIG. 11B) slope efficiency, (FIG. 11C) threshold current/current density, and (FIG. 11D) differential resistance as a function of the aperture size. The data represent the average of 50 device measurements with error bars. FIG. 11A, FIG. 11B, FIG. 11C, and FIG. 11D show plots the (FIG. 11A) output power/intensity, (FIG. 11B) slope efficiency, (FIG. 11C) threshold current/current density, and (FIG. 11D) differential resistance as a function of the aperture size. The data points represent the average value of all the devices tested for that particular aperture diameter with error bars. In FIG. 11A, the total output power increases almost linearly with increasing aperture sizes because of the enlarged emission areas. However, the emission intensity remained reasonably constant for the 10 μm and 15 μm but dropped for the 20 μm aperture. Given the filamentary nature of emission observed in the VCSELs, the average output power is expected to drop due to specular non-uniform emission from large apertures. The lower intensity of the 5 μm aperture may be due to the lasing spot being in close proximity to the non-ideal etch front divide in the nanoporous DBRs. We see similar trends for the slope efficiency in FIG. 11B, which correlates with the output power. The drop in slope efficiency for the 20 μm is likely a result of nonuniform current spreading in the ITO. More current is required near the center of the aperture to obtain the same power of stimulated emission occurring at the edge. The current spreading in the p-side can be significantly improved by replacing the ITO with a GaN-based TJ, which will also help reduce the layer absorption loss. Now for the threshold current, increasing the aperture size generally means an increased Iₜₕ as more current is needed to inject across a larger area to reach the same threshold current density. However, in FIG. 11C, the current density drastically changes from ˜60 kA/cm² for the 5 μm to ˜15 kA/cm² for the 10 μm aperture. This is primarily due to poor lateral confinement in the 5 μm apertures, in addition to the lasing spot being at a non-ideal location near where the EC etch fronts meet. FIG. 11D plots the differential resistance against the aperture size, where it drops gradually from ˜100 Ω to ˜34 Ω. All the VCSELs had the same device dimensions apart from the aperture diameters, meaning that the current flow was restricted in the axial direction for the smaller apertures resulting in the high differential resistance. The larger aperture sizes allow the flow of current at lower voltages. Overall, the trends in FIG. 11A-FIG. 11D highlight the importance of choosing the proper aperture diameters. Small apertures suffer from weak confinement, while large apertures suffer from filamentation and non-uniform current spreading. It appears that for the current design, 10 μm and 15 μm apertures are the most optimized. Addressing some of these issues in future designs will improve the device characteristic in other aperture sizes as well.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

While the present teachings have been illustrated with respect to one or more implementations, alterations and/or modifications can be made to the illustrated examples without departing from the spirit and scope of the appended claims. For example, it will be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or implementations of the present teachings. It will be appreciated that structural components and/or processing stages can be added or existing structural components and/or processing stages can be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. As used herein, the term “one or more of” with respect to a listing of items such as, for example, A and B, means A alone, B alone, or A and B. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “about” indicates that the value listed may be somewhat altered, as long as the alteration does not result in nonconformance of the process or structure to the illustrated implementation. Finally, “exemplary” indicates the description is used as an example, rather than implying that it is an ideal. Other implementations of the present teachings will be apparent to those skilled in the art from consideration of the specification and practice of the disclosure herein. It is intended that the specification and examples be considered as exemplary only, with a true scope and spirit of the present teachings being indicated by the following claims.

While the preferred embodiments have been shown and described, it will be understood that there is no intent to limit the invention by such disclosure, but rather, is intended to cover all modifications and alternate constructions falling within the spirit and scope of the invention.

What is claimed is:

1. A method for fabricating an electrically injected III-nitride vertical-cavity surface emitting laser (VCSEL) comprising:
providing an epitaxial structure comprising,
a non-c-plane substrate,
a lattice-matched bottom distributed Bragg reflector (DBR) comprising a plurality of alternating highly doped III-nitride layers and unintentionally doped III-nitride layers on the substrate,
an unintentionally doped (UID) III-nitride heat spreading layer,
an n+ III-nitride contact layer,
an n− III-nitride cladding layer,
an active region,
an electron blocking layer,
a p− III-nitride cladding layer, and
an p+ III-nitride contact layer;
etching a mesa to expose the n+ III-nitride contact layer;
patterning to define one or more current apertures;
ion implanting one or more apertures;
depositing a layer of SiO₂ to protect the active region and contact layers;
etching deep trenches to expose sidewalls of the lattice-matched bottom DBR; and
etching to selectively porosify the highly doped III-nitride layers to form a nanoporous DBR.

2. The method of claim 1, further comprising;
removing the layer of SiO₂;
patterning a layer of SiNₓ on the mesa and the trench to passivate sidewalls of the active region and the nanoporous DBR;
depositing an indium tin oxide (ITO) layer;
deposing an n metal and a p metal;
depositing a cavity spacer; and
deposing a top dielectric DBR.

3. The method of claim 1, wherein the substrate is at an angle between a c-plane and an m-plane of the substrate, including angles beyond the m-plane to minus c-plane (N face).

4. The method of claim 1, wherein the highly doped III-nitride layers and the unintentionally doped III-nitride layers comprise GaN, InₓGa₁₋ₓN, or AlₓGa₁₋ₓN.

5. The method of claim 1, further comprising controlling an amount of porosity in the highly doped III-nitride layers to provide a predetermined an index of refraction of the highly doped III-nitride layers of the nanoporous DBR.

6. The method of claim 5, wherein the porosity comprises a plurality of subwavelength air voids.

7. The method of claim 6, further comprising determining a pore size of the plurality of subwavelength air voids based on an electrochemical etch bias voltage, a doping level, and an etchant solution.

8. The method of claim 6, wherein a density of the plurality of subwavelength air voids is between about 20% and about 80%, or about 30% and about 70%, or about 40% and about 60%, or about 50%.

9. The method of claim 6, further comprising controlling a density of the plurality of subwavelength air voids based on a concentration of Si-doping.

10. The method of claim 1, wherein the non-c-plane III-nitride substrate is a nonpolar m-plane III-nitride substrate.

11. A method for fabricating an electrically injected III-nitride vertical-cavity surface emitting laser (VCSEL) comprising:
forming an epitaxial nanoporous bottom distributed Bragg reflector (DBR) comprising a plurality of alternating highly doped III-nitride layers and unintentionally doped III-nitride layers formed on a top surface of a substrate;
forming an active region above the bottom DBR;
forming ion-implanted apertures in an aperture layer above the active region and configured to allow current to flow through the VCSEL;
forming an unintentionally doped (UID) GaN heat spreading layer above the epitaxial nanoporous bottom DBR;
forming an indium tin oxide (ITO) layer above the UID GaN heat spreading layer; and
forming a cavity spacer above the ITO layer.

12. The method of claim 11, wherein the substrate is at an angle between a c-plane and an m-plane of the substrate, including angles beyond the m-plane to minus c-plane (N face).

13. The method of claim 11, wherein the highly doped III-nitride layers and the unintentionally doped III-nitride layers comprise GaN, InₓGa₁₋ₓN, or AlₓGa₁₋ₓN.

14. The method of claim 11, further comprising controlling an amount of porosity in the highly doped III-nitride layers to provide a predetermined an index of refraction of the highly doped III-nitride layers of the epitaxial nanoporous bottom DBR.

15. The method of claim 14, wherein the porosity comprises a plurality of subwavelength air voids.

16. The method of claim 15, further comprising determining a pore size of the plurality of subwavelength air voids based on an electrochemical etch bias voltage, a doping level, and an etchant solution.

17. The method of claim 15, wherein a density of the plurality of subwavelength air voids is between about 20% and about 80%, or about 30% and about 70%, or about 40% and about 60%, or about 50%.

18. The method of claim 15, further comprising controlling a density of the plurality of subwavelength air voids based on a concentration of Si-doping.

19. The method of claim 11, wherein the substrate is a non-c-plane III-nitride substrate.

20. The method of claim 11, wherein the substrate is a nonpolar m-plane III-nitride substrate.
